(19) United States
(12) Patent Application Publication
(10) Pub. No.: US 2026/0136845 A1
(43) Pub. Date: May 14, 2026

(54) WAFER AND METHOD OF MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Ikuo FUJIWARA, Yokohama (JP); Yosuke KAJIWARA, Yokohama (JP); Hiroshi ONO, Setagaya (JP); Jumpei TAJIMA, Mitaka (JP); Tatsuo SHIMIZU, Shinagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/023,995

(22) Filed: Jan. 16, 2025

(30) Foreign Application Priority Data
Mar. 8, 2024 (JP) 2024-036077

(51) Int. Cl. H10P 14/20; H10D 62/85; H10D 62/852

(52) U.S. Cl. CPC H10P 14/3416; H10P 14/3454; H10P 14/36; H10D 62/8503; H10D 62/852

(57) ABSTRACT

According to one embodiment, a wafer includes a first wafer and a second wafer. Each of the first wafer and the second wafer includes a nitride layer and a first layer. The nitride layer includes a first nitride region including Alₓ₁Ga₁₋ₓ₁N (0≤x1<1), and a second nitride region including Alₓ₂Ga₁₋ₓ₂N (0<x2≤1, x1<x2). The first layer includes a first member being crystal, and a second member being amorphous. The first member includes a first element including at least one element selected from the group consisting of Al, Hf, and Zr, and a second element including at least one element selected from the group consisting of oxygen and nitrogen. In a unit area, the first member has a first area facing the second nitride region. In the unit area, the second member has a second area facing the second nitride region.

### CROSS-REFERENCE TO RELATED APPLICATIONS

This application is based upon and claims the benefit of priority from Japanese Patent Application No. 2024-036077, filed on Mar. 8, 2024; the entire contents of which are incorporated herein by reference.

### FIELD

Embodiments described herein relate generally to a wafer and a method of manufacturing the same.

### BACKGROUND

For example, semiconductor devices and the like are manufactured using wafers including nitride. It is desired to improve the characteristics of wafers.

### BRIEF DESCRIPTION OF THE DRAWINGS

FIGS. 1A and 1B are schematic views illustrating a wafer according to a first embodiment;

FIGS. 2A and 2B are schematic views illustrating the wafer according to the first embodiment;

FIGS. 3A and 3B are schematic views illustrating a wafer according to the first embodiment;

FIGS. 4A and 4B are schematic views illustrating the wafer according to the first embodiment;

FIG. 5 is a schematic cross-sectional view illustrating a wafer according to the first embodiment;

FIG. 6 is a schematic cross-sectional view illustrating a wafer according to the first embodiment;

FIGS. 7A and 7B are schematic diagrams illustrating a wafer according to a second embodiment;

FIGS. 8A and 8B are schematic views illustrating a wafer according to the second embodiment; and

FIG. 9 is a flowchart illustrating a method for manufacturing a wafer according to a third embodiment.

### DETAILED DESCRIPTION

According to one embodiment, a wafer includes a first wafer and a second wafer. Each of the first wafer and the second wafer includes a nitride layer and a first layer. The nitride layer includes a first nitride region including Alₓ₁Ga₁₋ₓ₁N (0≤x1<1), and a second nitride region including Alₓ₂Ga₁₋ₓ₂N (0<x2≤1, x1<x2). The second nitride region is provided between the first nitride region and the first layer in a first direction. The first layer includes a first member being crystal, and a second member being amorphous. The first member includes a first element including at least one element selected from the group consisting of Al, Hf, and Zr, and a second element including at least one element selected from the group consisting of oxygen and nitrogen. In a unit area, the first member has a first area facing the second nitride region. In the unit area, the second member has a second area facing the second nitride region. The first wafer includes a first region. The second wafer includes a second region. A first ratio of the first area to the second area in the first region is lower than a second ratio of the first area to the second area in the second region. The first region and the second region satisfy at least one of a first condition, a second condition, or a third condition. In the first condition, a first intensity ratio is lower than a second intensity ratio. The first intensity ratio is a ratio of a first intensity at a first wavelength of 560 nm in first photoluminescent light obtained from the nitride layer included in the first region to a second intensity at a second wavelength of 350 nm in the first photoluminescent light. The second intensity is a ratio of a third intensity at the first wavelength in second photoluminescent light obtained from the nitride layer included in the second region to a fourth intensity at the second wavelength in the second photoluminescent light. In the second condition, a first photoluminescence wavelength in the nitride layer included in the first region is shorter than a second photoluminescence wavelength in the nitride layer included in the second region. In the third condition, a first thickness of the second nitride region included in the first region is thicker than a second thickness of the second nitride region included in the second region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

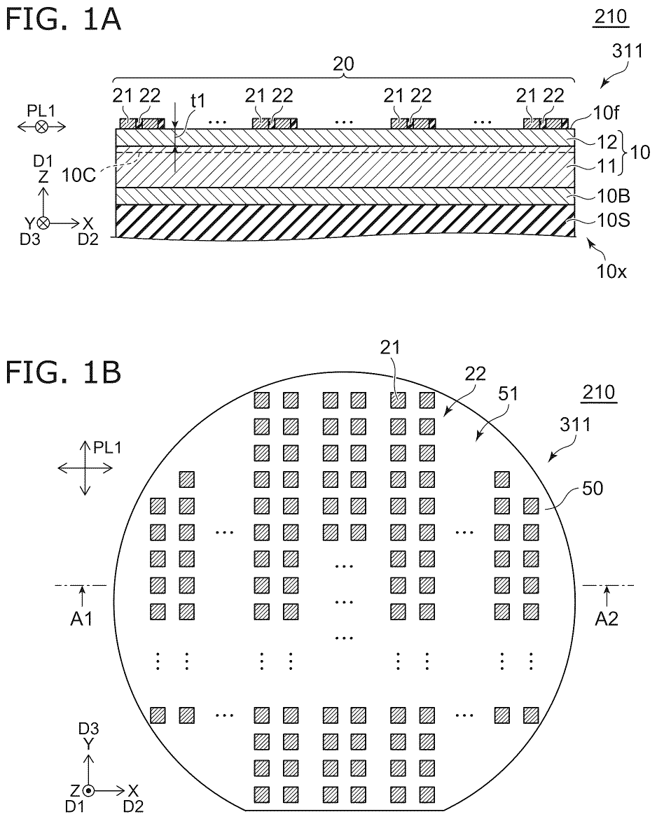

FIGS. 1A and 1B are schematic views illustrating a wafer according to the first embodiment.

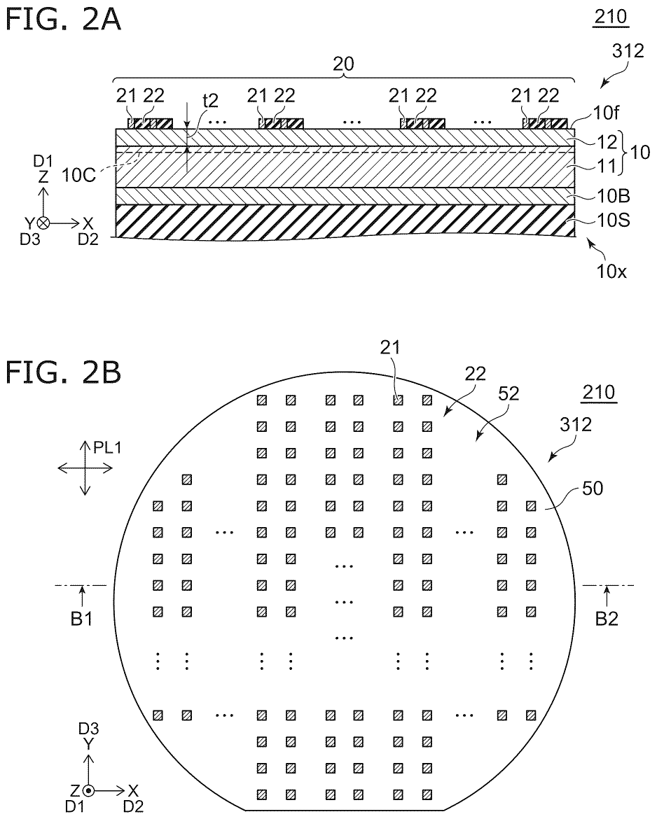

FIGS. 2A and 2B are schematic views illustrating the wafer according to the first embodiment.

FIG. 1A is a sectional view taken along the line A1-A2 in FIG. 1B. FIG. 1B is a plan view. FIG. 2A is a sectional view taken along the line B1-B2 in FIG. 2B. FIG. 2B is a plan view.

As shown in FIGS. 1A, 1B, 2A, and 2B, a wafer 210 (for example, a group of wafers) according to the embodiment includes a first wafer 311 and a second wafer 312.

Each of the first wafer 311 and the second wafer 312 includes a nitride layer 10 and a first layer 20. The nitride layer 10 includes a first nitride region 11 and a second nitride region 12.

The first nitride region 11 includes Alₓ₁Ga₁₋ₓ₁N (0≤x1<1). The composition ratio x1 may be, for example, 0 or more and 0.13 or less. The first nitride region 11 is, for example, a GaN layer.

The second nitride region 12 includes Alₓ₂Ga₁₋ₓ₂N (0<x2≤1, x1<x2). The composition ratio x2 may be, for example, not less than 0.15 and not more than 0.35. The second nitride region 12 is, for example, an AlGaN layer. The second nitride region 12 is provided between the first nitride region 11 and the first layer 20 in a first direction D1.

The first direction D1 is defined as a Z-axis direction. A direction perpendicular to the Z-axis direction is defined as an X-axis direction. A direction perpendicular to the Z-axis direction and the X-axis direction is defined as a Y-axis direction. The first nitride region 11 and the second nitride region 12 are layered substantially parallel to the X-Y plane.

As shown in FIGS. 1A and 2A, the first nitride region 11 includes a portion facing the second nitride region 12. A carrier region 10C is formed in this portion. The carrier region 10C is, for example, a two-dimensional electron gas. In operation of a semiconductor device based on wafer 210, carrier region 10C is utilized.

The first layer 20 includes a first member 21 being crystal, and a second member 22 being amorphous. FIG. 1B and FIG. 2B show one example of the pattern of the first member 21 and the second member 22. The first member 21 and the second member 22 are arranged in a first plane PL1 crossing the first direction D1.

In this example, the first member 21 includes a first material. The first material includes a first element including at least one element selected from the group consisting of Al, Hf, and Zr, and a second element including at least one element selected from the group consisting of oxygen and nitrogen. When the first member 21 includes such a first material, the carrier density in the nitride layer 10 increases due to the first member 21.

In one example, the first member 21 may include Alₓ₃Ga₁₋ₓ₃N (x2<x3≤1). The composition ratio x3 may be, for example, not less than 0.85 and not more than 1. The first member 21 may include, for example, AlN.

In a unit area, the first member 21 has a first area S1 facing the second nitride region 12. In the unit area, the second member 22 has a second area S2 facing the second nitride region 12. For example, the first member 21 may contact the second nitride region 12. The first area S1 per unit area is the area of the portion where the first member 21 contacts the second nitride region 12 in the unit area. For example, the second member 22 may contact the second nitride region 12. The second area S2 per unit area is the area of the portion where the second member 22 contacts the second nitride region 12 in the unit area.

The first area S1 in the example shown in FIG. 1B is larger than the second area S2 in the example shown in FIG. 2B.

The first wafer 311 includes a first region 51. The second wafer 312 includes a second region 52. A first ratio of the first area S1 to the second area S2 in the first region 51 is lower than a second ratio of the first area S1 to the second area S2 in the second region 52.

In the embodiment, the first region 51 and the second region 52 satisfy at least one of the following a first condition, a second condition, or a third condition.

In the first condition, a first intensity ratio R1 is lower than a second intensity ratio R2. The first intensity ratio R1 is a ratio of a first intensity at a first wavelength λ1 of 560 nm in the first photoluminescent light obtained from the nitride layer 10 included in the first region 51 to a second intensity at a second wavelength λ2 of 350 nm in the first photoluminescent light.

The second intensity ratio R2 is a ratio of a third intensity at the first wavelength λ1 in the second photoluminescent light obtained from the nitride layer 10 included in the second region 52 to a fourth intensity at the second wavelength λ2 in the second photoluminescent light.

The first wavelength λ1 of 560 nm is, for example, a wavelength corresponding to yellow light emission of GaN. The second wavelength λ2 of 350 nm corresponds to, for example, the wavelength of the emission near the band edge of GaN. For example, when the ratio of the intensity of the first wavelength λ1 to the intensity of the second wavelength λ2 is high, the carrier density in the nitride layer 10 is low. For example, when the ratio of the intensity of the first wavelength λ1 to the intensity of the second wavelength λ2 is low, the carrier density in the nitride layer 10 is high. The first condition corresponds to a state in which the carrier density in the first region 51 is higher than the carrier density in the second region 52.

In the second condition, a first photoluminescence wavelength in the nitride layer 10 included in the first region 51 is shorter than a second photoluminescence wavelength in the nitride layer 10 included in the second region 52.

When the photoluminescence wavelength is long, the carrier density is low. When the photoluminescence wavelength is short, the carrier density is high. The second condition corresponds to a state in which the carrier density in the first region 51 is higher than the carrier density in the second region 52.

In the third condition, a first thickness t1 (see FIG. 1A) of the second nitride region 12 included in the first region 51 is thicker than a second thickness t2 (see FIG. 2A) of the second nitride region 12 included in the second region 52.

When the first member 21 includes a small amount of the above-described first material and the second nitride region 12 is thin, the carrier density is low. When the second nitride region 12 is thick, the carrier density is high. The third condition corresponds to a state in which the carrier density in the first region 51 is higher than the carrier density in the second region 52.

Thus, when the carrier density in the first region 51 is higher than the carrier density in the second region 52 (the first to third conditions), the first ratio of the first area S1 to the second area S2 in the first region 51 is lower than the second ratio of the first area S1 to the second area S2 in the second region 52. The non-uniformity of the carrier density in the nitride layer 10 is corrected by the first layer 20. For example, the carrier density is made uniform in the first region 51 (first wafer 311) and the second region 52 (second wafer 312). It is possible to provide a wafer (for example, a wafer group) capable of improving characteristics.

In the embodiment, the difference in carrier density between two regions (two wafers) can be reduced. In the embodiments, the carrier density in one region may be corrected to a target value. For example, the carrier density in the first region 51 is corrected to a target value. The carrier density in the second region 52 may be corrected to a target value.

The first wafer 311 and the second wafer 312 may be included in different manufacturing lots, for example. The first wafer 311 and the second wafer 312 may be included in one manufacturing lot, for example. For example, the first wafer 311 and the second wafer 312 may be included in one set that includes multiple wafers.

In the embodiment, the first thickness t1 and the second thickness t2 may be values obtained by X-ray reflectance measurement. Thereby, a more accurate thickness can be obtained. For example, the first thickness t1 when the X-ray reflection intensity is high is thicker than the first thickness t1 when the X-ray reflection intensity is low. For example, the second thickness t2 when the X-ray reflection intensity is high is thicker than the second thickness t2 when the X-ray reflection intensity is low.

In the embodiment, the second member 22 may include, for example, silicon and at least one selected from the group consisting of nitrogen and oxygen.

As shown in FIGS. 1A and 2A, a plurality of the first members 21 may be provided. One of the plurality of first members 21 is provided between a part of the second member 22 and another part of the second member 22.

A plurality of the second members 22 may be provided. One of the plurality of second members 22 may be provided between a part of the first member 21 and another part of the first member 21.

The plurality of first members 21 and the plurality of second members 22 may be provided. One of the plurality of first members 21 may be provided between one of the plurality of second members 22 and another one of the plurality of second members 22. One of the plurality of second members 22 may be provided between one of the plurality of first members 21 and another one of the plurality of first members 21.

One of the plurality of first members 21 may be dot-like, stripe-like, or a combination of dot-like and stripe-like. One of the plurality of second members 22 may be dot-like, stripe-like, or a combination of dot-like and stripe-like. The first member 21 and the second member 22 may have a comb-teeth shape.

As shown in FIGS. 1A and 1B, the wafer 210 (first wafer 311 and second wafer 312) may further include a base 10S and a nitride member 10B. The nitride member 10B is provided on the base 10S. the first nitride region 11 is provided on the nitride member 10B. The second nitride region 12 is provided on the first nitride region 11. The first layer 20 is provided on the second nitride region 12. The base 10S may be, for example, a silicon substrate. The nitride member 10B includes Al, Ga, and N. The nitride member 10B is, for example, a buffer layer. The nitride layer 10 may be included in a structure 10x. The structure 10x may include the base 10S and the nitride member 10B.

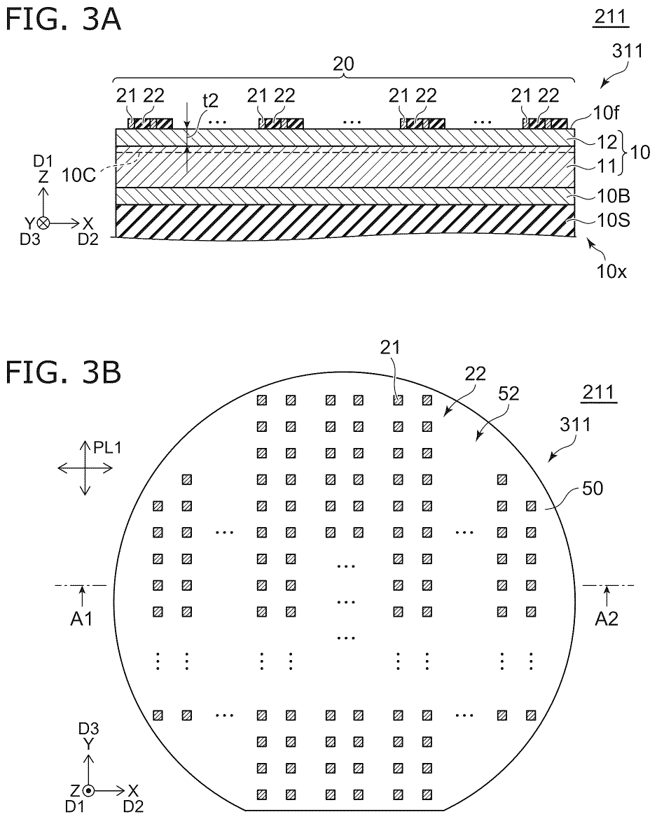

FIGS. 3A and 3B are schematic views illustrating a wafer according to the first embodiment.

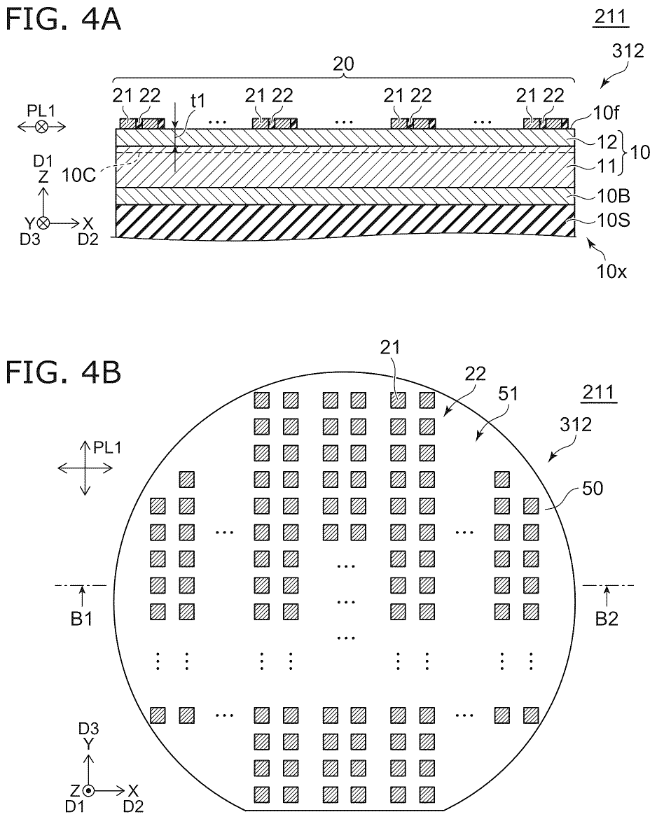

FIGS. 4A and 4B are schematic views illustrating the wafer according to the first embodiment.

FIG. 3A is a cross-sectional view taken along the line A1-A2 in FIG. 3B. FIG. 3B is a plan view. FIG. 4A is a sectional view taken along the line B1-B2 in FIG. 4B. FIG. 4B is a plan view.

As shown in FIGS. 3A, 3B, 4A, and 4B, a wafer 211 according to the embodiment includes the first wafer 311 and the second wafer 312. In the wafer 211, a second material includes Ga and nitrogen. The second material may be, for example, GaN. The second material may further include at least one of Mg, Zn, and C. The second material may be, for example, p-type (p-type GaN). In the wafer 211, the first ratio of the first area S1 to the second area S2 in the first region 51 is higher than the second ratio of the first area S1 to the second area S2 in the second region 52. The configuration of the wafer 211 except for this may be the same as the configuration of the wafer 210.

When the first member 21 includes the above second material, the carrier density in the nitride layer 10 is reduced by the first member 21.

In this case as well, the first region 51 and the second region 52 satisfy at least one of the first condition, the second condition, or the third condition.

As described above, under the first condition, the first intensity ratio R1 is higher than the second intensity ratio R2. The first intensity ratio R1 is a ratio of the first intensity at the first wavelength λ1 of 560 nm in first photoluminescent light obtained from the nitride layer 10 included in the first region 51 to the second intensity at the second wavelength λ2 of 350 nm in the first photoluminescent light. The second intensity ratio R2 is the ratio of the third intensity at the first wavelength λ1 in the second photoluminescent light obtained from the nitride layer 10 included in the second region 52 to the fourth intensity at the second wavelength λ2 in the second photoluminescent light.

In the second condition, the first photoluminescence wavelength in the nitride layer 10 included in the first region 51 is longer than the second photoluminescence wavelength in the nitride layer 10 included in the second region 52. In the third condition, the first thickness t1 of the second nitride region 12 included in the first region 51 is thinner than the second thickness t2 of the second nitride region 12 included in the second region 52. The first to third conditions correspond to a state in which the carrier density in the first region 51 is lower than the carrier density in the second region 52.

In such a case, by the area of the first member 21 including the second material (p-type GaN) being small, the carrier density can be relatively increased. For example, the first ratio of the first area S1 to the second area S2 in the first region 51 is set to be higher than the second ratio of the first area S1 to the second area S2 in the second region 52. The non-uniformity of the carrier density in the nitride layer 10 is corrected by the first layer 20. For example, the carrier density is made uniform in the first region 51 (first wafer 311) and the second region 52 (second wafer 312). It is possible to provide a wafer capable of improving characteristics.

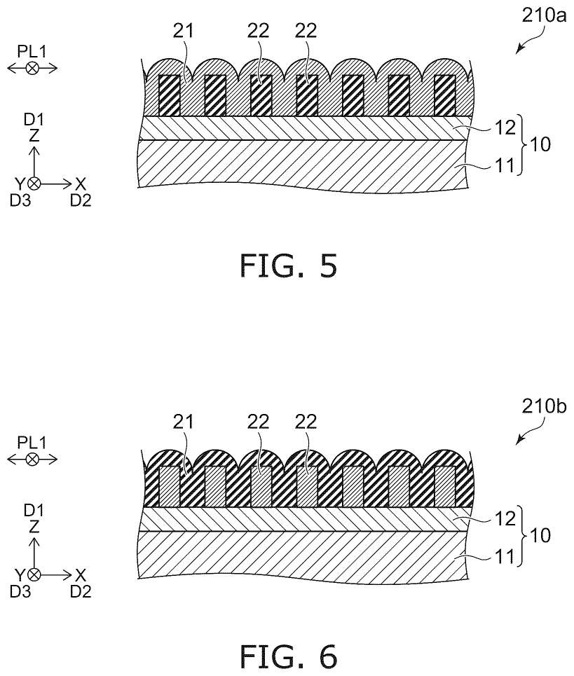

FIGS. 5 and 6 are schematic cross-sectional views illustrating a wafer according to the first embodiment.

As shown in FIG. 5, in a wafer 210a according to the embodiment, at least a part of the second member 22 is provided between the second nitride region 12 and a part of the first member 21. As shown in FIG. 6, in a wafer 210b according to the embodiment, at least a part of the first member 21 is provided between the second nitride region 12 and a part of the second member 22. Such a configuration may be applied to wafer 210 and wafer 211.

### Second Embodiment

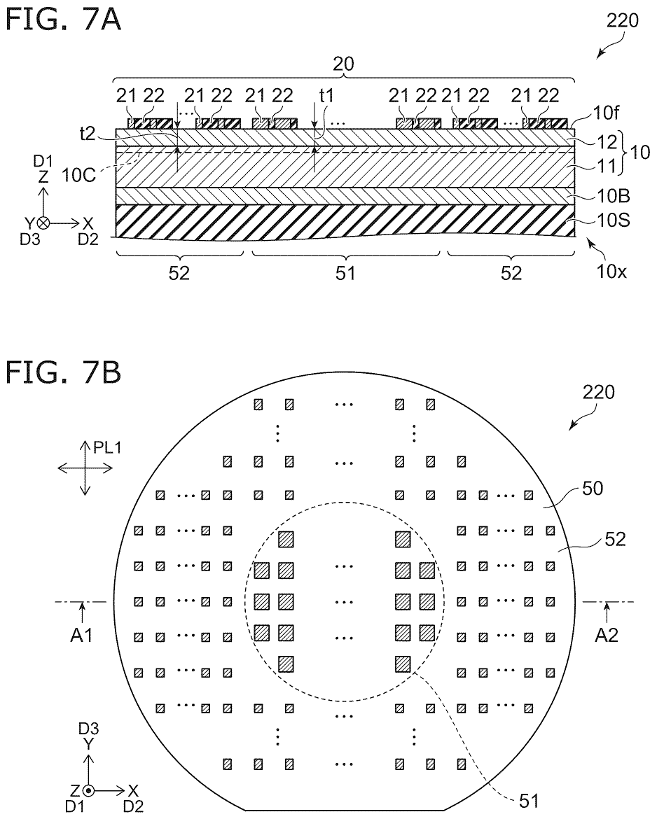

FIGS. 7A and 7B are schematic diagrams illustrating a wafer according to a second embodiment.

FIG. 7A is a sectional view taken along the line A1-A2 in FIG. 7B. FIG. 7B is a plan view.

A wafer 220 according to the embodiment includes the nitride layer 10 and the first layer 20. The nitride layer 10 includes the first nitride region 11 including Alₓ₁Ga₁₋ₓ₁N (0≤x1<1), and the second nitride region 12 including Alₓ₂Ga₁₋ₓ₂N (0<x2≤1, x1<x2).

The second nitride region 12 is provided between the first nitride region 11 and the first layer 20 in the first direction D1.

The first layer 20 includes the first member 21 being crystal and the second member 22 being amorphous. In this example, the first member 21 includes the first material. As already explained, the first material includes the first element including at least one element selected from the group consisting of Al, Hf, and Zr, and a second element including at least one element selected from the group consisting of oxygen and nitrogen.

In a unit area, the first member 21 has the first area S1 facing the second nitride region 12. In the unit area, the second member 22 has the second area S2 facing the second nitride region 12.

In the second embodiment, the nitride layer 10 includes the first region 51 and the second region 52. In the second embodiment, the first region 51 and the second region 52 are provided in one wafer 220. The first region 51 and the second region 52 are arranged in the first plane PL1 crossing the first direction D1. The first ratio of the first area S1 to the second area S2 in the first region 51 is lower than the second ratio of the first area S1 to the second area S2 in the second region 52.

The first region 51 and the second region 52 satisfy at least one of the first condition, the second condition, or the third condition.

As described above, in the first condition, the first intensity ratio R1 is lower than the second intensity ratio R2. The first intensity ratio R1 is the ratio of the first intensity at the first wavelength λ1 of 560 nm in first photoluminescent light obtained from the nitride layer 10 included in the first region 51 to the second intensity at the second wavelength λ2 of 350 nm in the first photoluminescent light. The second intensity ratio R2 is the ratio of the third intensity at the first wavelength λ1 in the second photoluminescent light obtained from the nitride layer 10 included in the second region 52 to the fourth intensity at the second wavelength λ2 in the second photoluminescent light.

In the second condition, the first photoluminescence wavelength in the nitride layer 10 included in the first region 51 is shorter than the second photoluminescence wavelength in the nitride layer 10 included in the second region 52.

In the third condition, the first thickness t1 of the second nitride region 12 included in the first region 51 is thicker than the second thickness t2 of the second nitride region 12 included in the second region 52.

In a case where at least one of the first to third conditions is satisfied, the first ratio of the first area S1 to the second area S2 in the first region 51 is higher than the second ratio of the first area S1 to the second area S2 in the second region 52. Thereby, for example, the carrier density in one wafer 220 can be corrected. Also in the second embodiment, a wafer capable of improving characteristics can be provided.

In the embodiment, the second region 52 may be provided around the first region 51. Alternatively, the first region 51 may be provided around the second region 52. The first region 51 and the second region 52 may be any region in the wafer 220.

In the wafer 220, the first member 21 may include Alₓ₃Ga₁₋ₓ₃N (x2<x3≤1).

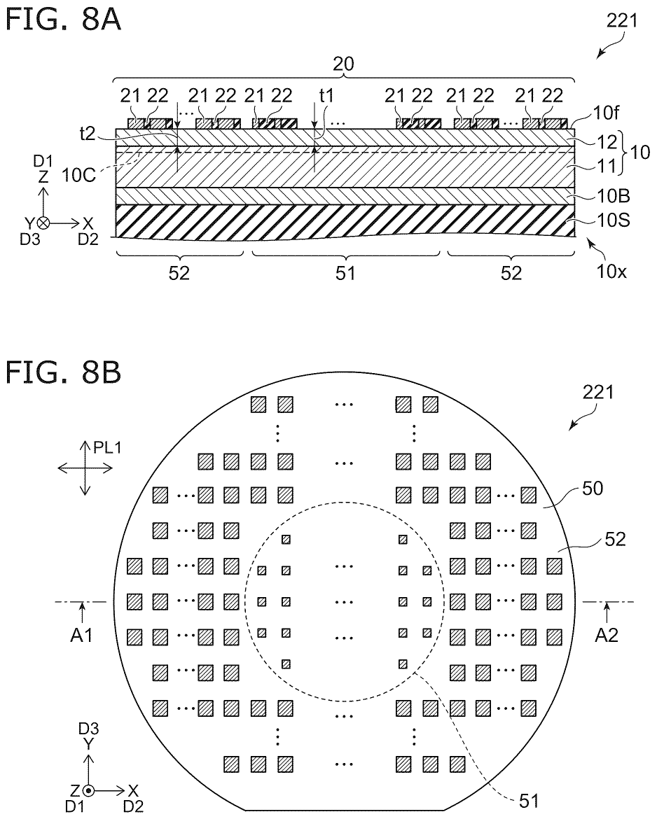

FIGS. 8A and 8B are schematic views illustrating a wafer according to the second embodiment.

FIG. 8A is a sectional view taken along the line A1-A2 in FIG. 8B. FIG. 8B is a plan view.

In a wafer 221 according to the embodiment, the second material includes Ga and nitrogen. The second material may be, for example, GaN. The second material may further include at least one of Mg, Zn, and C. The second material may be, for example, p-type (p-type GaN). In the wafer 221, the first ratio of the first area S1 to the second area S2 in the first region 51 is lower than the second ratio of the first area S1 to the second area S2 in the second region 52. The configuration of the wafer 221 except for this may be the same as the configuration of the wafer 220.

In a case where the first member 21 includes the above second material, the carrier density in the nitride layer 10 is reduced by the first member 21.

In this case as well, the first region 51 and the second region 52 satisfy at least one of the first condition, the second condition, or the third condition.

In a case where at least one of the first to third conditions is satisfied, the first ratio of the first area S1 to the second area S2 in the first region 51 is lower than the second ratio of the first area S1 to the second area S2 in the second region 52. Thereby, for example, the carrier density in one wafer 221 can be corrected. Also in the second embodiment, a wafer capable of improving characteristics can be provided.

In the embodiment, the second region 52 may be provided around the first region 51. Alternatively, the first region 51 may be provided around the second region 52. The first region 51 and the second region 52 may be any region on the wafer 221.

### Third Embodiment

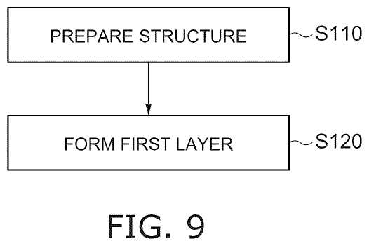

FIG. 9 is a flowchart illustrating a method for manufacturing a wafer according to a third embodiment.

As shown in FIG. 9, in a method for manufacturing the wafer according to the embodiment, the structure 10x including the nitride layer 10 is prepared (step S110).

The nitride layer 10 includes the first nitride region 11 and the second nitride region 12. The first nitride region 11 includes Alₓ₁Ga₁₋ₓ₁N (0≤x1<1). The second nitride region 12 is provided on the first nitride region 11. The second nitride region 12 includes Alₓ₂Ga₁₋ₓ₂N (0<x2≤1, x1<x2).

The first layer 20 is formed on the second nitride region 12 (step S120). The first layer 20 includes the first member 21 being crystal, and the second member 22 being amorphous.

In the embodiment, the processing conditions for at least one of the first member 21 or the second member 22 are changed based on at least one of a first information, a second information, and a third information.

The first information includes an intensity ratio of the first intensity at the first wavelength λ1 of 560 nm in photoluminescence light obtained from the nitride layer 10 to the second intensity at the second wavelength λ2 of 350 nm in the photoluminescence light. The second information includes a photoluminescence wavelength in the nitride layer 10. The third information includes the thickness of the second nitride region 12.

As described above, the first information, the second information, and the third information include information on the carrier density in the nitride layer 10.

Based on such information, processing conditions are changed. The processing conditions may include at least one of exposure conditions or etching conditions.

In one example, a film to be the first member 21 is formed on the second nitride region 12. The first member 21 is formed by processing this film. The processing is performed by photolithography and etching. The shape (size, area, etc.) of the first member 21 can be changed by changing the conditions of these steps. The second member 22 may be formed between the first members 21 obtained by the processing and on the first members 21.

In one example, a film to be the second member 22 is formed on the second nitride region 12. The second member 22 is formed by processing this film. The processing is performed by photolithography and etching. The shape (size, area, etc.) of the second member 22 can be changed by changing the conditions of these steps. he first member 21 may be formed between the second members 22 obtained by processing.

y such a method, a difference in area ratio between the first region 51 and the second region 52 can be obtained.

In the third embodiment, the first member 21 has the first area S1 facing the second nitride region 12 in the unit area. In the unit area, the second member 22 has the second area S2 facing the second nitride region 12. The ratio of the first area S1 to the second area S2 is controlled by processing conditions.

For example, the first member 21 includes the first material. The first material includes a first element including at least one element selected from the group consisting of Al, Hf, and Zr, and a second element including at least one element selected from the group consisting of oxygen and nitrogen.

The first information, second information, and third information being above described may have the following first state or second state. The intensity ratio in the first state is lower than the intensity ratio in the second state. The photoluminescence wavelength in the first state is shorter than the photoluminescence wavelength in the second state. The thickness of the second nitride region 12 in the first state is thicker than the thickness of the second nitride region 12 in the second state. The ratio of the first area S1 to the second area S2 in the first state is lower than the ratio of the first area S1 to the second area S2 in the second state. For example, non-uniformity or deviation in carrier concentration can be corrected.

On the other hand, the first member 21 may include the second material. The second material includes Ga and nitrogen. The second material may further include at least one of Mg, Zn, and C. In a case where the first member 21 includes such a first material, processing conditions may be controlled as follows. The intensity ratio in the first state is higher than the intensity ratio in the second state. The photoluminescence wavelength in the first state is longer than the photoluminescence wavelength in the second state. The thickness of the second nitride region 12 in the first state is thinner than the thickness of the second nitride region 12 in the second state. The ratio of the first area S1 to the second area S2 in the first state is higher than the ratio of the first area S1 to the second area S2 in the second state. For example, non-uniformity or deviation in carrier concentration can be corrected.

In the embodiment, processing conditions may be changed between one of the plurality of wafers and another one of the plurality of wafers.

In the embodiment, the processing conditions may be changed in the first region 51 within the plane of the wafer and the second region 52 within the plane of the same wafer. In the case where the first region 51 and the second region 52 are provided within the plane of one wafer, the exposure conditions may be changed for each exposure shot.

The embodiments may include the following Technical proposals:

### (Technical Proposal 1)

A wafer, comprising:
a first wafer; and
a second wafer,
each of the first wafer and the second wafer including a nitride layer and a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including a first element including at least one element selected from the group consisting of Al, Hf, and Zr, and a second element including at least one element selected from the group consisting of oxygen and nitrogen,
in a unit area, the first member having a first area facing the second nitride region,
in the unit area, the second member having a second area facing the second nitride region,
the first wafer including a first region,
the second wafer including a second region,
a first ratio of the first area to the second area in the first region being lower than a second ratio of the first area to the second area in the second region,
the first region and the second region satisfying at least one of a first condition, a second condition, or a third condition,
in the first condition, a first intensity ratio being lower than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being shorter than a second photoluminescence wavelength in the nitride layer included in the second region, and
in the third condition, a first thickness of the second nitride region included in the first region being thicker than a second thickness of the second nitride region included in the second region.

### (Technical Proposal 2)

A wafer, comprising:
a first wafer; and
a second wafer,
each of the first wafer and the second wafer including a nitride layer and a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including Ga and nitrogen,
in a unit area, the first member having a first area facing the second nitride region,
in the unit area, the second member having a second area facing the second nitride region,
the first wafer including a first region,
the second wafer including a second region,
a first ratio of the first area to the second area in the first region being higher than a second ratio of the first area to the second area in the second region,
the first region and the second region satisfying at least one of a first condition, a second condition, or a third condition,
in the first condition, a first intensity ratio being higher than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being longer than a second photoluminescence wavelength in the nitride layer included in the second region, and
in the third condition, a first thickness of the second nitride region included in the first region being thinner than a second thickness of the second nitride region included in the second region.

### (Technical Proposal 3)

A wafer, comprising:
a nitride layer; and
a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including a first element including at least one element selected from the group consisting of Al, Hf, and Zr, and a second element including at least one element selected from the group consisting of oxygen and nitrogen,
in a unit area, the first member having a first area facing the second nitride region,
in the unit area, the second member having a second area facing the second nitride region,
the nitride layer including a first region and a second region,
a first ratio of the first area to the second area in the first region being lower than a second ratio of the first area to the second area in the second region,
the first region and the second region satisfying at least one of a first condition, a second condition, or a third condition,
in the first condition, a first intensity ratio being lower than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being shorter than a second photoluminescence wavelength in the nitride layer included in the second region, and
in the third condition, a first thickness of the second nitride region included in the first region being thicker than a second thickness of the second nitride region included in the second region.

### (Technical Proposal 4)

The wafer according to Technical proposal 3, wherein
the second region is provided around the first region, or
the first region is provided around the first region.

### (Technical Proposal 5)

The wafer according to Technical proposal 3 or 4, wherein
the first member includes Alₓ₃Ga₁₋ₓ₃N (x2<x3≤1).

### (Technical Proposal 6)

A wafer, comprising:
a nitride layer; and
a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including Ga and nitrogen,
in a unit area, the first member having a first area facing the second nitride region,
in the unit area, the second member having a second area facing the second nitride region,
the nitride layer including a first region and a second region,
a first ratio of the first area to the second area in the first region being higher than a second ratio of the first area to the second area in the second region,
the first region and the second region satisfying at least one of a first condition, a second condition, or a third condition,
in the first condition, a first intensity ratio being higher than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being longer than a second photoluminescence wavelength in the nitride layer included in the second region, and
in the third condition, a first thickness of the second nitride region included in the first region being thinner than a second thickness of the second nitride region included in the second region.

### (Technical Proposal 7)

The wafer according to Technical proposal 6, wherein
the second region is provided around the first region, or
the first region is provided around the first region.

### (Technical Proposal 8)

The wafer according to any one of Technical proposals 1-7, wherein
the first thickness and the second thickness are values obtained by X-ray reflectance measurement.

### (Technical Proposal 9)

The wafer according to any one of Technical proposals 1-8, wherein
the first member and the second member are in contact with the second nitride region.

### (Technical Proposal 10)

The wafer according to any one of Technical proposals 1-9, wherein
the second member includes silicon and at least one selected from the group consisting of nitrogen and oxygen.

### (Technical Proposal 11)

The wafer according to any one of Technical proposals 1-10, wherein
at least a part of the second member is provided between the second nitride region and a part of the first member.

### (Technical Proposal 12)

The wafer according to any one of Technical proposals 1-10, wherein
at least a part of the first member is provided between the second nitride region and a part of the second member.

### (Technical Proposal 13)

The wafer according to any one of Technical proposals 1-12, wherein
a plurality of the first members are provided, and
one of the plurality of first members is provided between a part of the second member and another part of the second member.

### (Technical Proposal 14)

The wafer according to any one of Technical proposals 1-12, wherein
a plurality of the second members are provided, and
one of the plurality of second members is provided between a part of the first member and another part of the first member.

### (Technical Proposal 15)

A method for manufacturing a wafer, comprising:
preparing a structure including a nitride layer, the nitride layer including a first nitride region including Alₓ₁Ga₁₋ₓ₁N (0≤x1<1), and a second nitride region being provided on first nitride region and including Alₓ₂Ga₁₋ₓ₂N (0<x2≤1, x1<x2); and
forming a first layer on the second nitride region, the first layer including a first member being crystal and a second member being amorphous, and changing processing conditions for at least one of the first member and the second member based on at least one of a first information, a second information, or a third information,
the first information including an intensity ratio of a first intensity at a first wavelength of 560 nm in photoluminescence light obtained from the nitride layer to a second intensity at a second wavelength of 350 nm in the photoluminescence light,
the second information including a photoluminescence wavelength in the nitride layer, and
the third information including a thickness of the second nitride region.

### (Technical Proposal 16)

The method for manufacturing the wafer according to Technical proposal 15, wherein
the processing condition includes at least one of an exposure condition and an etching condition.

### (Technical Proposal 17)

The method for manufacturing the wafer according to Technical proposal 15 or 16, wherein
the first member has a first area facing the second nitride region in a unit area,
the second member has a second area facing the second nitride region in the unit area,
the first member includes a first element including at least one selected from the group consisting of Al, Hf, and Zr, and a second element including at least one selected from the group consisting of oxygen and nitrogen,
the intensity ratio in a first state is lower than the intensity ratio in a second state,
a photoluminescence wavelength in the first state is shorter than a photoluminescence wavelength in the second state,
a thickness in the first state is thicker than a thickness in the second state, and
a ratio of the first area to the second area in the first state is lower than a ratio of the first area to the second area in the second state.

### (Technical Proposal 18)

The method for manufacturing the wafer according to Technical proposal 15 or 16, wherein
the first member has a first area facing the second nitride region in a unit area,
the second member has a second area facing the second nitride region in the unit area,
the first member includes Ga and nitrogen,
the intensity ratio in a first state is higher than the intensity ratio in a second state,
a photoluminescence wavelength in the first state is longer than a photoluminescence wavelength in the second state,
a thickness in the first state is thinner than a thickness in the second state, and
a ratio of the first area to the second area in the first state is higher than a ratio of the first area to the second area in the second state.

### (Technical Proposal 19)

The method for manufacturing the wafer according to any one of Technical proposals 15-18, wherein
the processing condition is changed between one of the plurality of wafers and another one of the plurality of wafers.

### (Technical Proposal 20)

The method for manufacturing the wafer according to any one of Technical proposals 15-18, wherein
the processing condition is changed in a first region in a plane of the wafer and a second region in the plane of the wafer.

According to the embodiment, a wafer whose characteristics can be improved and a method for manufacturing the same can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the wafer such as nitride layers, nitride regions, layers, members, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers and all methods for manufacturing the same practicable by an appropriate design modification by one skilled in the art based on the wafers and the methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a first wafer; and
a second wafer,
each of the first wafer and the second wafer including a nitride layer and a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including a first element including at least one element selected from the group consisting of Al, Hf, and Zr, and a second element including at least one element selected from the group consisting of oxygen and nitrogen,
in a unit area, the first member having a first area facing the second nitride region,
in the unit area, the second member having a second area facing the second nitride region,
the first wafer including a first region,
the second wafer including a second region,
a first ratio of the first area to the second area in the first region being lower than a second ratio of the first area to the second area in the second region,
the first region and the second region satisfying at least one of a first condition, a second condition, or a third condition,
in the first condition, a first intensity ratio being lower than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being shorter than a second photoluminescence wavelength in the nitride layer included in the second region, and
in the third condition, a first thickness of the second nitride region included in the first region being thicker than a second thickness of the second nitride region included in the second region.

2. A wafer, comprising:
a first wafer; and
a second wafer,
each of the first wafer and the second wafer including a nitride layer and a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including Ga and nitrogen,
in a unit area, the first member having a first area facing the second nitride region,
in the unit area, the second member having a second area facing the second nitride region,
the first wafer including a first region,
the second wafer including a second region,
a first ratio of the first area to the second area in the first region being higher than a second ratio of the first area to the second area in the second region,
the first region and the second region satisfying at least one of a first condition, a second condition, or a third condition,
in the first condition, a first intensity ratio being higher than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being longer than a second photoluminescence wavelength in the nitride layer included in the second region, and
in the third condition, a first thickness of the second nitride region included in the first region being thinner than a second thickness of the second nitride region included in the second region.

3. A wafer, comprising:
a nitride layer; and
a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including a first element including at least one element selected from the group consisting of Al, Hf, and Zr, and a second element including at least one element selected from the group consisting of oxygen and nitrogen,
in a unit area, the first member having a first area facing the second nitride region,
in the unit area, the second member having a second area facing the second nitride region,
the nitride layer including a first region and a second region,
a first ratio of the first area to the second area in the first region being lower than a second ratio of the first area to the second area in the second region,
the first region and the second region satisfying at least one of a first condition, a second condition, or a third condition,
in the first condition, a first intensity ratio being lower than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being shorter than a second photoluminescence wavelength in the nitride layer included in the second region, and
in the third condition, a first thickness of the second nitride region included in the first region being thicker than a second thickness of the second nitride region included in the second region.

4. The wafer according to claim 3, wherein the second region is provided around the first region, or the first region is provided around the first region.

5. The wafer according to claim 3, wherein
the first member includes Alₓ₃Ga₁₋ₓ₃N (x2<x3≤1).

6. A wafer, comprising:
a nitride layer; and
a first layer,
the nitride layer including a first nitride region including Alₓ₁Ga₁₋ₓ₁N (0≤x1<1), and a second nitride region including Alₓ₂Ga₁₋ₓ₂N (0<x2≤1, x1<x2),
the second nitride region being provided between the first nitride region and the first layer in a first direction,
the first layer including a first member being crystal, and a second member being amorphous,
the first member including Ga and nitrogen,
in a unit area, the first member having a first area facing the second nitride region,
in the unit area, the second member having a second area facing the second nitride region,
the nitride layer including a first region and a second region,
a first ratio of the first area to the second area in the first region being higher than a second ratio of the first area to the second area in the second region,
the first region and the second region satisfying at least one of a first condition, a second condition, or a third condition,
in the first condition, a first intensity ratio being higher than a second intensity ratio,
the first intensity ratio being a ratio of a first intensity at a first wavelength of 560 nm in first photoluminescent light obtained from the nitride layer included in the first region to a second intensity at a second wavelength of 350 nm in the first photoluminescent light,
the second intensity being a ratio of a third intensity at the first wavelength in second photoluminescent light obtained from the nitride layer included in the second region to a fourth intensity at the second wavelength in the second photoluminescent light,
in the second condition, a first photoluminescence wavelength in the nitride layer included in the first region being longer than a second photoluminescence wavelength in the nitride layer included in the second region, and
in the third condition, a first thickness of the second nitride region included in the first region being thinner than a second thickness of the second nitride region included in the second region.

7. The wafer according to claim 6, wherein
the second region is provided around the first region, or
the first region is provided around the first region.

8. The wafer according to claim 1, wherein
the first thickness and the second thickness are values obtained by X-ray reflectance measurement.

9. The wafer according to claim 1, wherein
the first member and the second member are in contact with the second nitride region.

10. The wafer according to claim 1, wherein
the second member includes silicon and at least one selected from the group consisting of nitrogen and oxygen.

11. The wafer according to claim 1, wherein
at least a part of the second member is provided between the second nitride region and a part of the first member.

12. The wafer according to a claim 1, wherein
at least a part of the first member is provided between the second nitride region and a part of the second member.

13. The wafer according to claim 1, wherein
a plurality of the first members are provided, and
one of the plurality of first members is provided between a part of the second member and another part of the second member.

14. The wafer according to claim 1, wherein
a plurality of the second members are provided, and
one of the plurality of second members is provided between a part of the first member and another part of the first member.

15. A method for manufacturing a wafer, comprising:
preparing a structure including a nitride layer, the nitride layer including a first nitride region including Alₓ₁Ga₁₋ₓ₁N (0≤x1<1), and a second nitride region being provided on first nitride region and including Alₓ₂Ga₁₋ₓ₂N (0<x2≤1, x1<x2); and
forming a first layer on the second nitride region, the first layer including a first member being crystal and a second member being amorphous, and changing processing conditions for at least one of the first member and the second member based on at least one of a first information, a second information, or a third information,
the first information including an intensity ratio of a first intensity at a first wavelength of 560 nm in photoluminescence light obtained from the nitride layer to a second intensity at a second wavelength of 350 nm in the photoluminescence light,
the second information including a photoluminescence wavelength in the nitride layer, and
the third information including a thickness of the second nitride region.

16. The method according to claim 15, wherein
the processing condition includes at least one of an exposure condition and an etching condition.

17. The method according to claim 15, wherein
the first member has a first area facing the second nitride region in a unit area,
the second member has a second area facing the second nitride region in the unit area,
the first member includes a first element including at least one selected from the group consisting of Al, Hf, and Zr, and a second element including at least one selected from the group consisting of oxygen and nitrogen,
the intensity ratio in a first state is lower than the intensity ratio in a second state,
a photoluminescence wavelength in the first state is shorter than a photoluminescence wavelength in the second state,
a thickness in the first state is thicker than a thickness in the second state, and
a ratio of the first area to the second area in the first state is lower than a ratio of the first area to the second area in the second state.

18. The method according to claim 15, wherein
the first member has a first area facing the second nitride region in a unit area,
the second member has a second area facing the second nitride region in the unit area,
the first member includes Ga and nitrogen,
the intensity ratio in a first state is higher than the intensity ratio in a second state,
a photoluminescence wavelength in the first state is longer than a photoluminescence wavelength in the second state,
a thickness in the first state is thinner than a thickness in the second state, and
a ratio of the first area to the second area in the first state is higher than a ratio of the first area to the second area in the second state.

19. The method according to claim 15, wherein
the processing condition is changed between one of the plurality of wafers and another one of the plurality of wafers.

20. The method according to claim 15, wherein
the processing condition is changed in a first region in a plane of the wafer and a second region in the plane of the wafer.
